(19) United States
(12) Patent Application Publication
(10) Pub. No.: US 2014/0301774 A1
(43) Pub. Date: Oct. 9, 2014

(54) HOUSING OF ELECTRONIC DEVICE AND METHOD FOR MANUFACTURING THE HOUSING

(71) Applicants: HON HAI PRECISION INDUSTRY CO., LTD., New Taipei (TW); Fu Tai Hua Industry (Shenzhen) Co., Ltd., Shenzhen (CN)

(72) Inventor: XIAO CHEN, Shenzhen (CN)

(73) Assignees: HON HAI PRECISION INDUSTRY CO., LTD., New Taipei (TW); FU TAI HUA INDUSTRY (SHENZHEN) CO., LTD., Shenzhen (CN)

(21) Appl. No.: 14/231,881

(22) Filed: Apr. 1, 2014

(30) Foreign Application Priority Data
Apr. 9, 2013 (CN) 2013101202769

(51) Int. Cl. H05K 5/00

(52) U.S. Cl. CPC H05K 5/0004
USPC 403/267; 156/91

(57) ABSTRACT

Method for manufacturing housing of electronic device. A first housing and a second housing are provided. The first housing includes a first sidewall and a second sidewall. Thermal shrinkage of the second housing can be different from that of the first housing. The second housing includes a first peripheral wall and second peripheral wall. Thermal curing glue coats on either the first sidewall or the first peripheral wall, and thermal curing glue coats on either the second sidewall or the second peripheral wall. The first sidewall with contacts with the first peripheral wall, and the second sidewall contacts with the second peripheral wall. Tthe first peripheral wall is fastened to the first sidewall, and the second peripheral wall is fastened to the second sidewall. The thermal curing glue is heated. The first and second housing is cooled.

### FIELD

The present disclosure relates to housings, particularly to a housing of electronic device and method for manufacturing the housing of electronic device.

### BACKGROUND

A housing of electronic device, for example a housing of a mobile phone or a housing of a tablet computer, can consist of two or more than two housings of different material. For example, for improving a signal receiving quality, a plastic housing and a metal housing are used in a housing of electronic device. The plastic housing covers an antenna to decrease a shielding of signals. The plastic housing and the metal housing can be coupled by thermal curing glue.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout several views.

FIG. 1 is an exploded, isometric view of an embodiment of a housing of an electronic device.

FIG. 2 is an isometric view of the housing of the electronic device of FIG. 1.

FIG. 3 is a flowchart showing a method for manufacturing the housing of electronic device of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

The term “coupled” is defined as connected, whether directly or indirectly through intervening components, and is not necessarily limited to physical connections. The connection can be such that the objects are permanently connected or releasably connected.

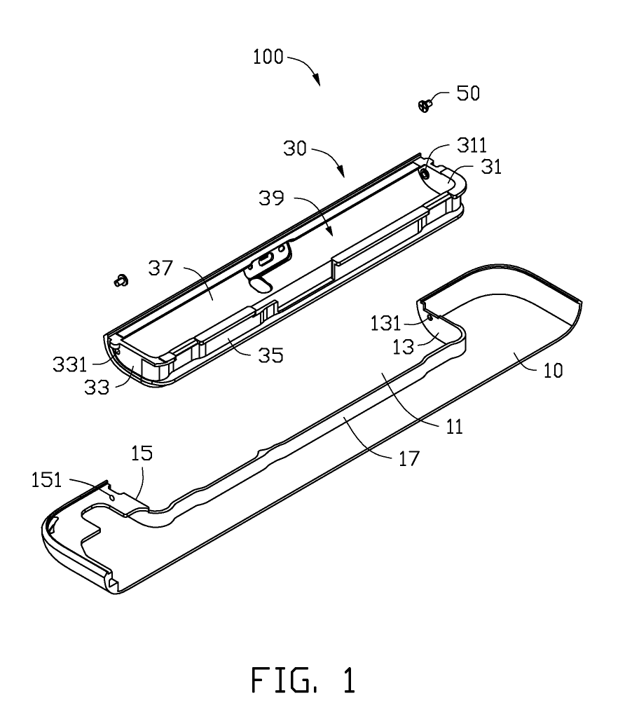

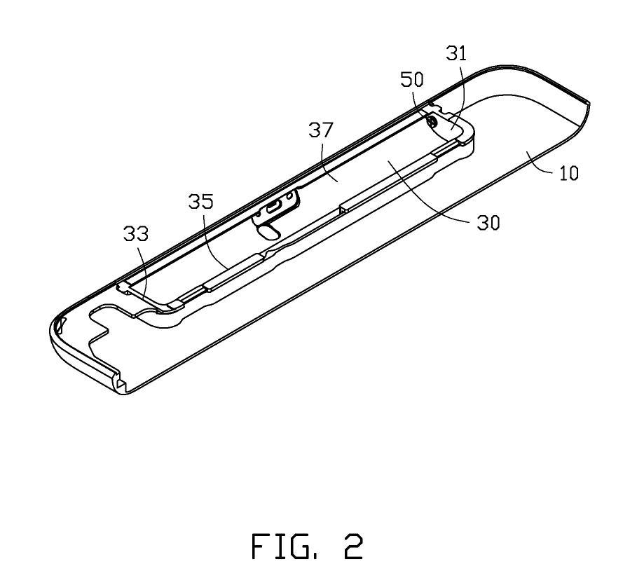

FIGS. 1 and 2 show an embodiment of a housing 100 of an electronic device. The housing 100 can include a first housing 10, a second housing 30 can be adhered to the first housing 10, and a plurality of fasteners 50 fastening the first housing 10 and the second housing 30. The first housing 10 and the second housing 30 can be made of different materials, and a thermal shrinkage of the first housing 10 can have a different thermal shrinkage as compared with the second housing 30. In the illustrated embodiment, the first housing 10 can be made of metal, and the second housing can be made of plastic.

The first housing 10 can include a first sidewall 13, a second sidewall 15, and a third sidewall 17. The first sidewall 13, the second sidewall 15, and the third sidewall 17 can cooperatively define an opening 11. In the illustrated embodiment, the opening 11 can be U-shaped. The first sidewall 13 can be located opposite to the second sidewall 15. The third sidewall 17 can be located between the first sidewall 13 and the second sidewall 15, and can interconnect the first sidewall 13 and the second sidewall 15. A length of the third sidewall 17 can be longer than a length of the first sidewall 13, and can be longer than a length of the second sidewall 15. The first sidewall 13 can define a first locking hole 131. The second sidewall 15 can define a second locking hole 151 (being blocked and shown in dash lines in FIG. 1). The first locking hole 131 and the second locking hole 151 can be configured to lock with corresponding one of the plurality of fasteners 50.

A shape of the second housing 30 can match a shape of the opening 11. The second housing 30 can be adhered to the first housing 10 by thermal curing glue. The second housing 30 can be received in the opening 11. The second housing 30 can include a first peripheral wall 31, a second peripheral wall 33, a third peripheral wall 35, and a bottom wall 37. The first peripheral wall 31 can be located opposite to the second peripheral wall 33. The third peripheral wall 35 can be located between the first peripheral wall 31 and the second peripheral wall 33, and can be coupled to the first peripheral wall 31 and the second peripheral wall 33. The bottom wall 37 can be an arcuate wall and can be coupled to the first peripheral wall 31, the second peripheral wall 33, and the third peripheral wall 35. The first peripheral wall 31 can be adhered to the first sidewall 13 by the thermal curing glue. The second peripheral wall 33 can be adhered to the second sidewall 15 by the thermal curing glue. The third peripheral wall 37 can be adhered to the third sidewall 17 by the thermal curing glue. The bottom wall 37 can cover the opening 11. The first peripheral wall 31, the second peripheral wall 33, the third peripheral wall 35, and the bottom wall 37 can define a receiving chamber 39, cooperatively, for receiving electrical elements of an electronic device, for example an antenna.

The first peripheral wall 31 can define a first through hole 311 corresponding to the first locking hole 131. The second peripheral wall 33 can define a second through hole 331 corresponding to the second locking hole 151. In the illustrated embodiment, a number of the plurality of fasteners 50 is two. One of the two fasteners 50 can be inserted into the first through hole 311 and the first locking hole 131 to lock the first sidewall 13 and the first peripheral wall 31. Another one of the two fasteners 50 can be inserted into the second through hole 331 and the second locking hole 151 to lock the second sidewall 15 and the second peripheral wall 33.

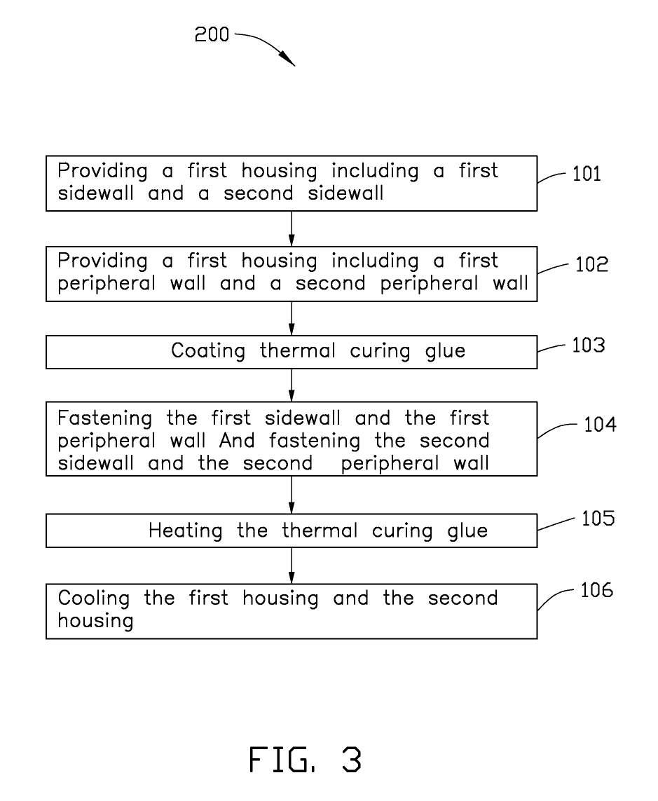

FIG. 3 illustrates an embodiment of a method 200 for manufacturing a housing of electronic device, which can be as described above.

In 101, the first housing can be provided. The first housing can define an opening. The first housing can include a first sidewall, a second sidewall, and a third sidewall surrounding the opening. The first sidewall can define a first locking hole. The second sidewall can define a second locking hole.

In 102, a second housing which has a different thermal shrinkage than the first housing can be provided. The second housing can include a first peripheral wall, a second peripheral wall, a third peripheral wall, and a bottom wall. The first peripheral wall can define a first through hole. The second peripheral wall can define a second through hole.

In 103, the second housing can be received in the opening, and thermal curing glue can be coated between the first peripheral wall and the first sidewall, and can be coated between the second peripheral wall and the second sidewall, and can be coated between the third peripheral wall and the third sidewall. The first sidewall can be made to contact the first peripheral wall, the second sidewall can be made to contact the second peripheral wall, the third peripheral wall can be made to contact the third sidewall. In the illustrated embodiment, the thermal curing glue can be coated on either the first sidewall or the first peripheral wall, and can be coated on either the second sidewall or the second peripheral wall, and can be coated on either the third sidewall or the third peripheral wall.

In 104, two fasteners can be provided. One fastener can be inserted into the first through hole and the first locking hole to lock the first sidewall and the first peripheral wall, another one fastener can be inserted into the second through hole and the second locking hole to lock the second sidewall and the second peripheral wall.

In 105, the thermal curing glue can be heated, and then the first peripheral wall can be adhered to the first sidewall, the second peripheral wall can be adhered to the second sidewall, the third peripheral wall can be adhered to the third sidewall. When the first housing and the second housing are heated, a shrinkage degree of the first housing is different than a shrinkage degree of the second housing, and the fasteners can restrict a deviation of the second housing relative to the first housing.

In 106, the first housing and the second housing can be cooled to obtain the housing of electronic device. When the first housing and the second housing are cooled, the fasteners can counteract a shear force of the thermal curing glue, to avoid the second housing loosening from the first housing.

In an alternative embodiment, the third peripheral wall can be not adhered to the third sidewall, and only the first peripheral wall can be adhered to the first sidewall and the second peripheral wall can be adhered to the second sidewall. The third peripheral wall can be fastened to the third sidewall and can be not adhered to the third sidewall before heating the first housing and the second housing.

It is believed that the present embodiments and their advantages will be understood from the foregoing description, and it will be apparent that various changes can be made thereto without departing from the spirit and scope of the embodiments or sacrificing all of its material advantages.

What is claimed is:

1. A housing of electronic device comprising:
a first housing comprising a first sidewall and a second sidewall opposite to the first sidewall, and defining an opening between the first sidewall and the second sidewall;
a second housing received in the opening and adhered to the first housing by thermal curing glue, a thermal shrinkage of the second housing different from a thermal shrinkage of the first housing, the second housing comprising a first peripheral wall and second peripheral wall opposite to the first peripheral wall, the first peripheral wall adhered to the first sidewall by thermal curing glue, the second peripheral wall adhered to the second sidewall by thermal curing glue; and
two fasteners, one of the two fasteners fastened the first peripheral wall to the first sidewall, and another one of the two fasteners fastened the second peripheral wall to the second sidewall.

2. The housing of electronic device of claim 1, wherein the first sidewall defines a first locking hole, the second sidewall defines a second locking hole, the first peripheral wall defines a first through hole, the second peripheral wall defines a second through hole, one of one of the two fasteners is inserted into the first through hole and the first locking hole to fasten the first peripheral wall to the first sidewall, and another one of the two fasteners is inserted into the second through hole and the second locking hole to fasten the second peripheral wall to the second sidewall.

3. The housing of electronic device of claim 1, wherein the first housing further comprises a third sidewall, the third sidewall is coupled to the first sidewall and the second sidewall, the first sidewall, the second sidewall, and the third sidewall define the opening, cooperatively, the second housing further comprises a third peripheral wall coupled with the first peripheral wall and the second peripheral wall, the third peripheral wall and the third sidewall are adhered together by thermal curing glue.

4. The housing of electronic device of claim 3, wherein the second housing further comprises a bottom wall coupled to the first peripheral wall, the second peripheral wall, and the third peripheral wall, the bottom wall covers the opening.

5. The housing of electronic device of claim 3, wherein the third peripheral wall is fastened to the third sidewall.

6. A method for manufacturing housing of electronic device comprising:
providing a first housing, the first housing defining an opening and comprising a first sidewall and a second sidewall opposite to the first sidewall, the opening located between the first sidewall and the second sidewall;
providing a second housing which a thermal shrinkage of the second housing different from a thermal shrinkage of the first housing, the second housing comprising a first peripheral wall and second peripheral wall opposite to the first peripheral wall;
putting the second housing into the opening, coating thermal curing glue between the first sidewall and the first peripheral wall, coating thermal curing glue between the second sidewall and the second peripheral wall, contacting the first sidewall with the first peripheral wall, and contacting the second sidewall with the second peripheral wall;
providing two fasteners, one of the two fasteners fastening the first peripheral wall to the first sidewall, and another one of the two fasteners fastening the second peripheral wall to the second sidewall;
heating the thermal curing glue between the first sidewall and the first peripheral wall, and the thermal curing glue between the second sidewall and the second peripheral wall;
cooling the first housing and the second housing to obtain the housing of electronic device.

7. The method of claim 6, wherein the first sidewall defines a first locking hole, the second sidewall defines a second locking hole, the first peripheral wall defines a first through hole, the second peripheral wall defines a second through hole, one of one of the two fasteners is inserted into the first through hole and the first locking hole to fasten the first peripheral wall to the first sidewall, and another one of the two fasteners is inserted into the second through hole and the second locking hole to fasten the second peripheral wall to the second sidewall.

8. The method of claim 7, wherein the first housing further comprises a third sidewall, the third sidewall is coupled to the first sidewall and the second sidewall, the first sidewall, the second sidewall, and the third sidewall define the opening, cooperatively, the second housing further comprises a third peripheral wall coupled with the first peripheral wall and the second peripheral wall, the third peripheral wall and the third sidewall are adhered together by thermal curing glue before heating.

9. The method of claim 8, wherein the second housing further comprises a bottom wall coupled to the first peripheral wall, the second peripheral wall, and the third peripheral wall, when the second housing is received in the opening, the bottom wall covers the opening.

10. The method of claim 8, wherein before heating, the third wall and the third peripheral wall are fastened together.

11. A method for manufacturing housing of electronic device comprising:
providing a first housing, the first housing comprising a first sidewall and a second sidewall;
providing a second housing, a thermal shrinkage of the second housing different from a thermal shrinkage of the first housing, the second housing comprising a first peripheral wall and second peripheral wall;
coating thermal curing glue on either the first sidewall or the first peripheral wall, and coating thermal curing glue on either the second sidewall or the second peripheral wall;
contacting the first sidewall with the first peripheral wall, and contacting the second sidewall with the second peripheral wall;
providing two fasteners, one of the two fasteners fastening the first peripheral wall to the first sidewall, and another one of the two fasteners fastening the second peripheral wall to the second sidewall;
heating the thermal curing glue between the first sidewall and the first peripheral wall, and heating the thermal curing glue between the second sidewall and the second peripheral wall;
cooling the first housing and the second housing.

12. The method of claim 11, wherein the first sidewall defines a first locking hole, the second sidewall defines a second locking hole, the first peripheral wall defines a first through hole, the second peripheral wall defines a second through hole, one of one of the two fasteners is inserted into the first through hole and the first locking hole to fasten the first peripheral wall to the first sidewall, and another one of the two fasteners is inserted into the second through hole and the second locking hole to fasten the second peripheral wall to the second sidewall.

13. The method of claim 12, wherein the first housing further comprises a third sidewall, the third sidewall is coupled to the first sidewall and the second sidewall, the second housing further comprises a third peripheral wall coupled with the first peripheral wall and the second peripheral wall, the third peripheral wall and the third sidewall are adhered together by thermal curing glue before heating.

14. The method of claim 13, wherein the second housing further comprises a bottom wall coupled to the first peripheral wall, the second peripheral wall, and the third peripheral wall.

15. The method of claim 13, wherein before heating, the third wall and the third peripheral wall are fastened together.
